(19) United States
(12) Patent Application Publication
(10) Pub. No.: US 2004/0177311 A1
(43) Pub. Date: Sep. 9, 2004

(54) Method for converting input bits into modulation symbols

(76) Inventors: Matthias Marke, Grobenzell (DE); Wen Xu, Unterhaching (DE)

Correspondence Address: BELL, BOYD & LLOYD, LLC, P. O. BOX 1135, CHICAGO, IL, 60690-1135, US

(21) Appl. No.: 10/477,004

(22) PCT Filed: Apr. 11, 2002
(86) PCT No.: PCT/DE02/01358

(51) Int. Cl. H03M 13/00

(52) U.S. Cl. 714/781

(57) ABSTRACT

A method is provided for converting input bits into modulation symbols. The modulation symbols include bit positions which are differentiated at least partially in terms of their channel error sensitivity. Convolutionally coded input bits are generated from the input bits using generator polynomials with a prioritization value being allocated to each of the convolutionally coded input bits. The reproduction of the convolutionally coded input bits on the bit positions of the modulation symbols is carried out, taking into account both the channel error sensitivity of the bit positions of the modulation symbols and the prioritization value of the convolutionally coded input bit.

### BACKGROUND OF THE INVENTION

The present invention relates to a method for converting input bits into modulation symbols, in particular with the inclusion of convolutional coding.

Source signals such as voice, sound, image and video almost always contain static redundancy. This redundancy may be removed through the source coding to permit efficient transmission and/or storage of the source signal. At the other end, it is necessary during the signal transmission to selectively reintroduce redundancy through channel coding to prevent channel interference. It is known for convolutional coding to be carried out as channel coding.

Flexible multi-rate encoding and adaptive decoding is frequently necessary since the data to be transferred usually requires varying levels of error protection and/or the transmission channel is time-varied and/or not (completely) known. Flexible multi-rate encoding also involves source and/or channel coding, which enables source signals to remove more or less redundant information as required, or to add error protection.

Because of the complexity of convolutional coding, one or a very few convolutional codes (parent codes) are used in a transmission system. A convolutional code is normally described by so-called generator polynomials via which input bits of the convolutional code are converted into convolutionally coded or channel-coded code bits. In the context of the present application, generator polynomials also refers to a quotient of generator polynomials. Convolutional coding itself is sufficiently understood in the subject field, which is why there is no further explanation of it here. A multi-rate coding scheme is normally implemented by puncturing (removal) of code bits (punctured convolutional/PC code) and/or by repetition of code bits (repetition convolutional/RC code) after the convolutional coding. Alternatively, the use of so-called insertion convolutional (IC) codes is also known. These codes are implemented to increase error protection by inserting known dummy bits, at both the send and receive ends, into the information bits before convolutional coding is carried out.

In digital communication, (channel-coded) bits (code bits) are normally transferred in modulated form. Using modulation techniques, the code bits are combined into symbols or mapped on to them. In higher-order modulation processes, in particular, this leads to a situation in which the bit positions that are allocated to a modulation symbol display different channel error sensitivity on the basis of their relative phases and/or amplitude layer. Higher channel error sensitivity results in lower reliability for the correct reception of a bit position if the modulation symbol is transferred via a faulty channel.

An object of the present invention is, therefore, to provide a method for converting input bits to modulation symbols that permits more reliable transmission of input bits compared to the prior art.

### SUMMARY OF THE INVENTION

Accordingly, the present invention is based on the fundamental idea that convolutionally coded input bits (i.e., code bits), which are based on the convolutional coding of input bits, are allocated a prioritization value, and the mapping of the convolutionally coded input bits on bit positions of the modulation symbols is carried out taking into account the channel error sensitivity of the bit positions of the modulation symbols and the prioritization value of the convolutionally coded input bits. The prioritization value describes the relevance of a convolutionally coded input bit (code bit) for error-correcting convolutional decoding at the receiving end. In particular, the convolutionally coded input bits are mapped on to bit positions of the modulation symbols such that preferentially convolutionally coded input bits which have a relatively high prioritization value are mapped on to bit positions of the modulation symbols that have relatively low error sensitivity. “Relatively high/low” here refers to above/below the corresponding average value.

Further embodiments of the present invention provide for special rules for allocating prioritization values to convolutionally coded input bits. These rules describe the result of costly simulations with simulation tools specially created for this purpose. The application of these rules, accordingly, leads to the reliable transmission of input bits.

Additional features and advantages of the present invention are described in, and will be apparent from, the following Detailed Description of the Invention.

### DETAILED DESCRIPTION OF THE INVENTION

If an insertion code is used, dummy bits with a known value on both the send and receive ends are inserted in fixed positions in the data stream of, for example, voice-coded data. Rules for the allocation of prioritization values to convolutionally coded input bits, for a case in which the input bits contain dummy bits, are specified below. These have been found to be particularly advantageous in the simulations described above. Furthermore, rules are specified for reproducing convolutionally coded input bits (code bits) on bit positions of the modulation symbols taking into account the channel error sensitivity of the bit positions of the modulation symbols and the prioritization values of the convolutionally coded input bits, which likewise have been found to be particularly advantageous in the simulations described above. The prioritization values are, accordingly, allocated as follows (1=highest priority, 6=lowest priority):

1. All convolutionally coded information bits; i.e., all bits that are based on a convolutional coding of information bits. (According to one embodiment of the present invention, special convolutionally coded information bits may be removed in order to achieve a lower level of protection for certain information bits (cf., example below). These removed bits are then allocated priority 6.

2. Systematic bits (bits which are mapped to themselves by the convolutional coding (e.g., if the generator polynomial is G4/G4=1, the calculation of the code bit delivers the value of the underlying information bit, these systematic bits being highly error-sensitive) of the convolutionally coded scheduling bits (bits that are transmitted as well for the scheduling of the convolutional code).

3. Convolutionally coded dummy bit, whose relevance for an error-correcting convolutional decoding on the receive end is at its greatest (this also results from the knowledge that the relevance of a convolutionally coded input bit for error-correcting convolutional decoding on the receive end depends on the corresponding generator polynomials used).

4. Remaining convolutionally coded dummy bits.

5. Remaining convolutionally coded scheduling bits.

6. Bits specially removed from prioritization value 1 (according to an alternative embodiment of the present invention).

The convolutionally coded input bits (code bits) are distributed to the modulation symbols according to the following stages:

1. Start with the bits (code bits) with the highest prioritization value.

2. Place as many bits as possible from this prioritization value on bit positions with the lowest channel error sensitivity.

3. If there are more bits available from the prioritization value to be placed than there are free bit positions with lowest channel error sensitivity, then the following rules apply:

Where bits that are allocated the same prioritization value are placed, preference is given to the bits whose relevance for an error-correcting convolutional decoding on the receive end is at its greatest (results from the knowledge that the relevance of a convolutionally coded input bit for error correcting convolutional decoding on the receive end depends on the corresponding generator polynomial used).

If a subset of equally sensitive bits must be placed, the placed bits are distributed equally to a frame of information bits. For example, if only 3 more free bit positions with lower channel error sensitivity exist for the 6 bits a,b,c,d,e, which have the same prioritization value, then the bits a,c,e are allocated first to the 3 bit positions with the lower channel error sensitivity.

Then proceed with stage 5.

4. If all bits with the priority value being placed are placed on to bit locations with the lowest channel error sensitivity and bit locations are still free there, the bits with next lowest priority value are placed according to rules 2 to 5.

5. If all bit locations with lowest channel error sensitivity are occupied, the bit locations with the next lowest channel error sensitivity are allocated to positions with the lowest channel error sensitivity according to rules 2 to 4.

The bits as yet unplaced are now placed according to rules 2 to 5.

The following exemplary embodiment considers an EDGE 8PSK channel in which the bits to be transferred are combined into symbols of 3 bits according to modulation. Of the 3 bits forming the 8PSK symbol, one bit (weak bit) has considerably higher channel error sensitivity than the other bits (strong bits). This channel is to be used for the transmission of voice signals that have been source-coded with the adaptive multi-rate voice codec using the lowest data rate of 4.75 kbit/s.

If an insertion code is used, a code rate 1/4 is selected for the convolutional coder. The generator polynomial

G4/G4=1

G5/G4=1+D+D⁴+D⁶/1+D²+D³+D⁵+D⁶

G6/G4=1+D+D²+D³+D⁴+D⁶/1+D²+D³+D⁵+D⁶

G7/G4=1+D+D²+D³+D⁶/1+D²+D³+D⁵+D⁶

is used in this circumstance. 224 8PSK modulation symbols are available for the voice information; thus, 448 strong bits and 224 weak bits. The 101 information bits (95 voice bits plus 6 CRC bits) are produced in the channel coding with rate 14 404 code bits. The inserted dummy bits are then added. 82 dummy bits are to be inserted in this case. The convolutional coding results in 328 bits of which the 82 systematic bits can be punctured. There remain 246 bits to be transferred. 6 scheduling bits are necessary for scheduling of the code with memory 6, which produce 24 bits when coded. Of these, 2 bits are punctured. There are 22 bits remaining.

The results for the 6 prioritization values are as follows:

1. 395 bits (all coded information bits, with the exception of bits 1,2,3,5,6,7,9,10,11, to which a lower priority is allocated to balance the better protection that the bits close to the output status experience in the trellis, see 6th priority).

2. 6 bits.

3. 82 bits (coded bits with G7/G4).

4. 164 bits (coded bits with G5/G4 and G6/G4).

5. 16 bits.

6. 9 bits (information bits 1,2,3,5,6,7,9,10,11).

The placement of the code bits on the bit positions of the modulation symbols then takes place according to the following stages:

1. Place the bits in prioritization value 1 in strong bit positions.

2. Place the bits in prioritization value 2 in strong bit positions.

3. 47 places remain available on strong bits for prioritization value 3. Consequently, for example, all 42 bits with the exact bit number within the prioritization value (these are then bit numbers 0,1, . . . 81) and, in addition, the bits 9,25,41,57,73, are positioned on strong bits. The remaining bits are positioned on weak bits.

4. The prioritization values 4, 5 and 6 are completely placed on weak bit positions.

Another embodiment of the present invention provides for convolutionally coded repetition bits to be allocated a relatively low prioritization value if repetition codes are used. The expression “convolutionally coded repetition bit” here refers both to the convolutional coding of a repetition bit and to the repetition of a convolutionally coded bit. This embodiment is based on the knowledge that, if an output bit of the convolutional coder is repeated to increase the data rate, the multiple transmission makes this bit less sensitive to channel errors. Therefore, such convolutionally coded repetition bits may be mapped on to bit positions with relatively high channel error sensitivity.

If a repetition code with code rate 1/4 of the convolutional code and a necessary effective code rate of 1/7 is used, 3 output bits of the channel coder are repeated. For example, a recursive systematic convolutional (RSC) code is used with the following generator polynomials:

G4/G4=1

G5/G4=1+D+D⁴+D⁶/1+D²+D³+D⁵+D⁶

G6/G4=1+D+D²+D³+D⁴+D⁶/1+D²+D³+D⁵+D⁶

G7/G4=1+D+D²+D³+D⁶/1+D²+D³+D⁵+D⁶

G4/G4=1

G5/G4=1+D+D⁴+D⁶/1+D²+D³+D⁵+D⁶

G6/G4=1+D+D²+D³+D⁴+D⁶/1+D²+D³+D⁵+D⁶

It can be seen from this list that the last 3 generator polynomials are a repetition of the first 3 generator polynomials.

The 7 bits that are output by the convolutional coder, if the frame bit u(k) is present on input, are: {C(7k), C(7k+1), C(7k+2), C(7k+3), C(7k+4), C(7k+5), C(7k+6)}. Of the bits transferred in duplicate, one or two bits now can be placed on weak bits. The higher channel error sensitivity of these bit locations is then compensated for by the repetition. Thus, for example, the allocation may be as follows (with underlined bits being placed on strong bits): {C(7k), C(7k+1), C(7k+2), C(7k+3), C(7k+4), C(7k+5), C(7k+6)}.

Although the present invention has been described with reference to specific embodiments, those of skill in the art will recognize that changes may be made thereto without departing from the spirit and scope of the present invention as set forth in the hereafter appended claims.

1. Method for converting input bits into modulation symbols,
in which the modulation symbols comprise bit positions which are differentiated at least partially in terms of their channel error sensitivity,
in which convolutionally coded input bits are generated from the input bits by means of generator polynomials, a prioritization value being allocated to each of said convolutionally coded input bits,
in which the mapping of the convolutionally coded input bits on the bit positions of the modulation symbols is carried out, taking into account the channel error sensitivity of the bit positions of the modulation symbols and the prioritization values of the convolutionally coded input bits.

2. Method according to claim 1,
in which the input bits contain information bits.

3. Method according to one of the preceding claims,
in which the input bits contain dummy bits whose value is known on the receive and transmit end.

4. Method according to one of the preceding claims,
in which the input bits contain scheduling bits for scheduling of the convolutional code.

5. Method according to claim 4,
in which convolutionally coded information bit is allocated a higher prioritization value than systematic bits of convolutionally coded scheduling bits.

6. Method according to claim 4 or 5,
in which the systematic bit of convolutionally coded scheduling bits is allocated a higher prioritization value than the convolutionally coded dummy bit with the highest prioritization value.

7. Method according to one of claims 4 to 6,
in which the convolutionally coded dummy bit with the lowest prioritization value is allocated a higher prioritization value than the non-systematic bits of convolutionally coded scheduling bits.

8. Method according to one of the preceding claims, in which certain convolutionally coded information bits are allocated the lowest prioritization value.

9. Method according to one of the preceding claims,
in which the input bits include repetition bits,
in which the convolutionally coded repetition bits are preferentially mapped on bit locations of the modulation symbols with a high channel error sensitivity.
